(19) United States
(12) Patent Application Publication
(10) Pub. No.: US 2003/0020548 A1
(43) Pub. Date: Jan. 30, 2003

(54) Clock and data regenerator different data rates

(76) Inventors: Jorg Sommer, Munchen (DE); Bernd Stilling, Munchen (DE)

Correspondence Address: BELL, BOYD & LLOYD, LLC, P. O. BOX 1135, CHICAGO, IL, 60690-1135, US

(21) Appl. No.: 09/979,609

(22) PCT Filed: Mar. 6, 2001
(86) PCT No.: PCT/DE01/00847

(30) Foreign Application Priority Data
Mar. 6, 2000 (DE) 10010947.0

(51) Int. Cl. H03L 7/00

(52) U.S. Cl. 331/1 A

(57) ABSTRACT

The clock and data regenerator comprises a control loop which is controlled by a phase discriminator (PD) and two frequency discriminators (FD1, FD2). The first frequency discriminator (FD1) enlarges the catchment range of the control loop in a known manner. The second frequency discriminator (FD2) determines the ratio of the bit rates of the clock signal (TS) which it produces itself and of the data signal (DSF). It sets the loop frequency divider (6) appropriately, and supplies a control voltage for setting the oscillator (5) until the first frequency discriminator (FD1) can carry out this function.

The invention relates to a clock and data regenerator for different data rates having a phase and frequency control device as claimed in the precharacterizing clause of patent claim 1.

Phase locked loops, referred to as PLLs for short, are used in order to recover the clock signal from a received binary signal, and to obtain a regenerated data signal using this clock signal.

In a clock regeneration device, the control loop is chosen to have a narrow bandwidth in order that the frequency and phase remain constant even in the event of a long sequence of zeros or ones. However, a stable phase locked loop has a very narrow catchment range. This means that the clock recovery operates only in a very narrow frequency range—that is to say essentially for only one quite specific bit rate.

A phase locked loop (PLL) which has a phase discriminator and a frequency discriminator is described in “Frequency Detectors for PLL Acquisition in Timing and Carrier Recovery” by David G. Messerschmitt, IEEE Transaction Communication, Vol. COM-27, pp. 1288-1295, September 1979. The frequency discriminator is used first of all to set the oscillator frequency approximately, and the phase angled between the clock signal that is produced and the data signal is then kept constant via the phase locked loop. In practice, these phase locked loops have a catchment range of approximately ±30% of the data signal frequency (bit rate).

If the clock regeneration is intended to be used for different data rates, then the catchment range of the PLL is frequently inadequate.

An apparatus for obtaining a clock signal from a data signal using a bit rate identification device for the received data signal is known from Laid-Open Specification DE 197 04 299 A1. The bit rate identification device is supplied with various reference signals, which allow the flank densities of the received data signal and of the reference signals to be compared. The result of this comparison is used to set a frequency divider in the feedback path such that the phase control becomes successfully effective. This apparatus is particularly suitable for a small number of bit rates, which are known at the receiving end.

The object of the invention is to specify a clock and data regenerator which reliably processes different bit rates of the data signal without any gaps. This clock and data regenerator is intended to be developed such that differently coded data signals can also be processed.

This object is achieved by a clock and data regenerator as claimed in claim 1.

Advantageous developments of the invention are specified in the dependent claims.

One particular advantage is the universal applicability and [lacuna] of the regenerator by virtue of its wide operating range. Generally, there is no need for a reference clock, but such a clock can be used in order to allow the frequency divider to be pre-set.

The major advantage is achieved by a further frequency discriminator, which sets a frequency divider arranged in the feedback loop of the control loop and adjusts a comparison frequency, which is obtained from the oscillator frequency, to such an extent that it enters the catchment range of the first frequency discriminator.

In a simpler embodiment, the frequency divider is adjusted in steps while, in the case of embodiments which operate at higher speeds, the divider can be preset directly on the basis of the measurement results from the further frequency discriminator. The two frequency discriminators can, of course, be combined in the circuitry.

The invention will be explained in more detail with reference to exemplary embodiments.

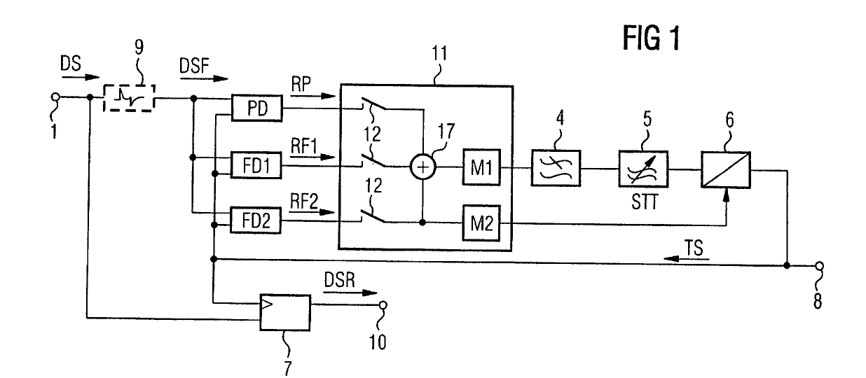

FIG. 1 shows the clock and data regenerator according to the invention,

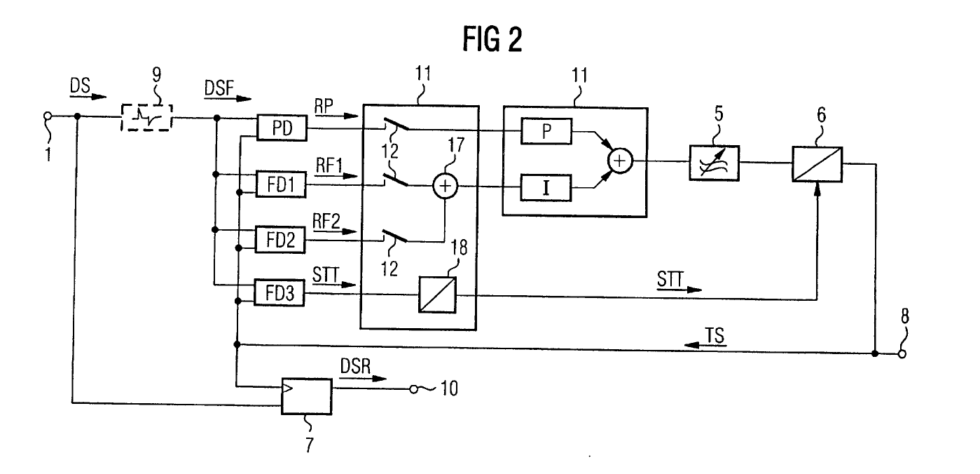

FIG. 2 shows a variant of the clock and data regenerator,

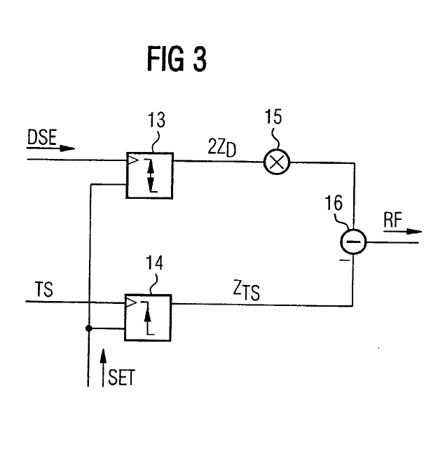

FIG. 3 shows an exemplary embodiment of the second frequency discriminator and

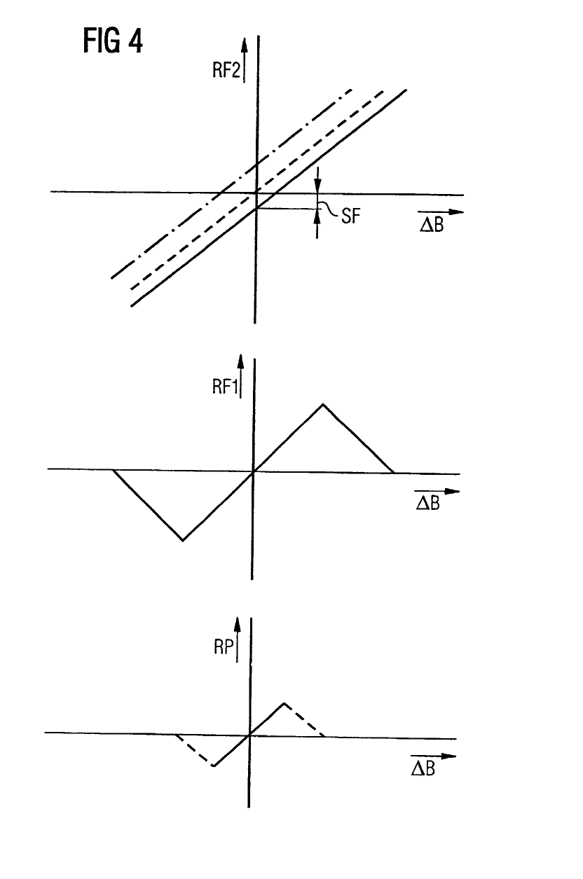

FIG. 4 shows control characteristics for the discriminators.

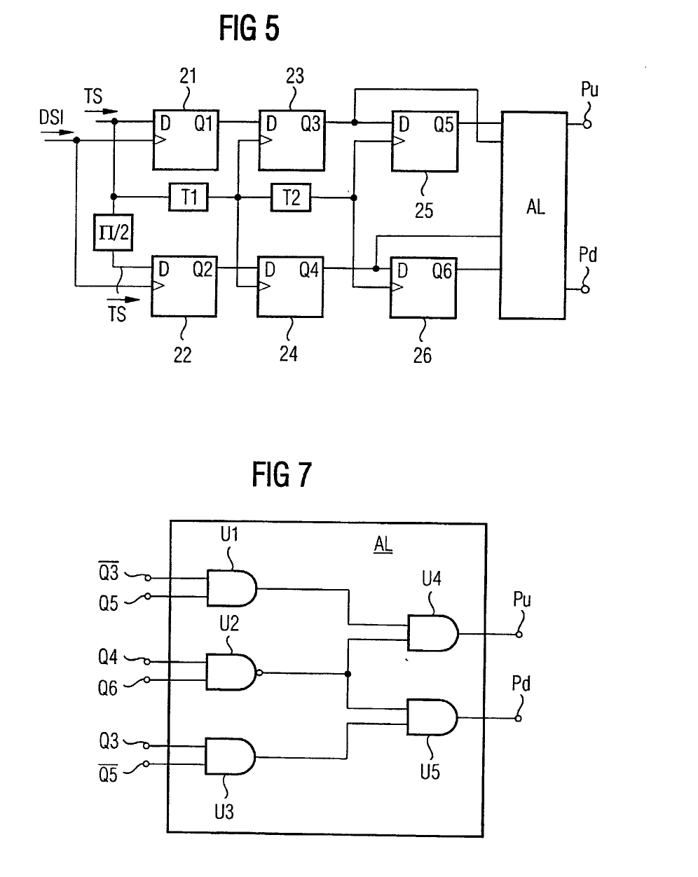

FIG. 5 shows an exemplary embodiment of the first frequency discriminator,

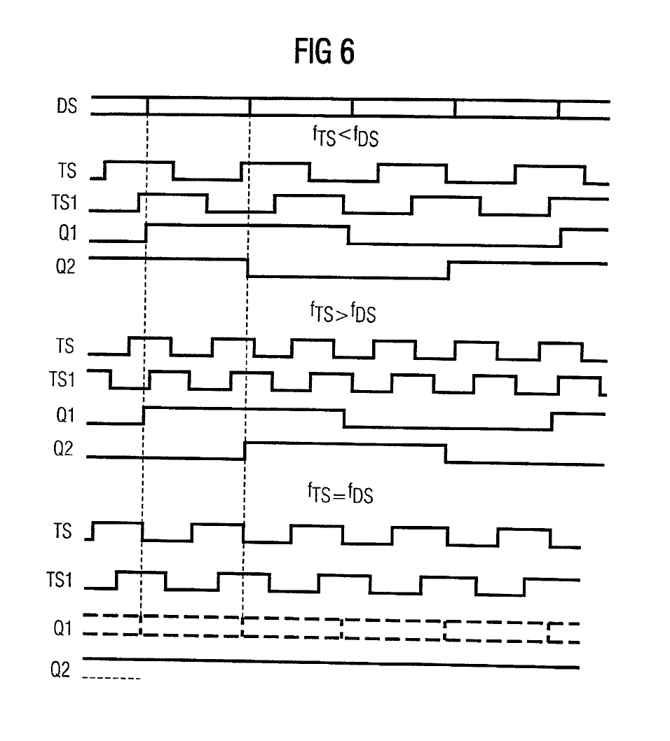

FIG. 6 shows a timing diagram and,

FIG. 7 shows the logic structure of an evaluation logic device.

FIG. 1 shows the outline circuit diagram of the regenerator according to the invention, which has frequency control and phase control. The phase locked loop (PLL) is formed from a phase discriminator PD, a loop filter, a controllable oscillator 5 and a frequency divider 6, which produces a clock signal TS which is fed back to a second input of the phase discriminator PD. The data signal DSF is used as a reference signal. This may be the data signal DS received at the signal input 1, or a data signal DSP derived from this signal in a signal conditioning device 9. This signal conditioning converts each flank of the data signal to, for example, a positive flank. This may be expedient when the received data signal is an NRZ signal (non return to zero) and does not have the desired fundamental frequency.

The frequency control is in each case carried out by means of a first frequency discriminator FD1 and a second frequency discriminator FD2, to both of which the clock signal TS, which is emitted at the output of the frequency divider, is likewise supplied. The received data signal is also supplied to a decision maker 7, which samples it using the clock signal and emits it as a regenerated data signal DSR at the data output 10. The clock signal is available at a clock signal output 8.

A controller 11 is also provided, which controls resynchronization and switches the frequency divider 6 such that the nominal frequency of the clock signal can be reached by the pull-in range of the controllable oscillator.

However, the function of the clock and data regenerator will be explained first of all on the basis of a variant illustrated in FIG. 2. This has a third frequency discriminator FD3, to which an external reference signal KF is supplied. The frequency discriminator FD3 separately counts the number of flanks of the data signal DS and the number of flanks of the reference signal KF within a predetermined time period. It is expedient to set the oscillator frequency approximately to the center of the pull-in range in advance. The controller uses the flank densities to determine the bit rate of the data signal and, initially, sets a division ratio for the frequency divider 6 for which the second frequency discriminator FD2 can at least roughly set the nominal frequency of the oscillator. The second frequency discriminator FD2 supplies (since there are generally even greater frequency differences between the reference signal and the clock signal after setting of the frequency divider) a control signal RF2 to the loop filter 4, which ensures further adaptation. This frequency discriminator has the advantage of a very wide operating range; however, it may not be sufficiently accurate if the transmission code is unknown, and the probability of a data flank occurring is hence unknown. Since it determines its control signal in the same way that the third frequency discriminator FD3 determines the bit rate of the data signal, it can also carry out its task.

The frequency discriminators FD3, FD2 ensure that the clock and data regenerator can operate reliably for widely differing data signal bit rates.

The function of the second and third frequency discriminators will now be explained in more detail. FIG. 3 shows the associated block diagram. This contains a first counter 13, whose clock input is supplied with the data signal flanks (in each case one pulse for each positive and negative flank of an NRZ signal), and a second counter 14, which counts each positive flank of the clock signal TS (further counters may also be positioned upstream of these counters, so that only each n-th flank is counted). At the end of one counting period, the results are subtracted from one another in a subtractor 16, in order to obtain a control criterion which is dependent on the frequency difference ΔB. The counters are then reset by means of a set pulse SET. A multiplier 15 (which is positioned downstream from one of the counters) can act as a correction element in order to slightly correct the count result of the signal flank counter. In the case of stochastic NRZ data, the probability of occurrence of a data flank is 0.5 per bit. A control criterion RF2=2Z_{D}−Z_{TS} can be obtained by the second frequency discriminator by forming the differences between the count values of the data flanks and of the positive clock flanks.

The bit rate is

$${B}_{s} = \frac{2 {Z}_{n}}{T} ,$$

where T is the measurement time, likewise on the assumption that the probability of occurrence of a data flank is 0.5.

The measurement error is in this case dependent on the number of measured bits, or on the measurement time. Furthermore, the probability of occurrence of a data flank is exactly 0.5 only in the case of stochastic NRZ-coded data. For normal transmission codes, the expected value for the occurrence of a step changeover is, however, between 0.5 and 0.625 per bit for CMI code, so that it is possible for there to be a systematic measurement error SF, depending on the code. At the top, FIG. 4 shows the characteristics for various codes. The solid characteristic shows the systematic measurement error SF of the control signal. If a mean expected value of 0.5625 is assumed, then the error is somewhat more than 10%. The second frequency discriminator thus means that the frequency control has a sufficient margin in order to achieve the catchment range of ±30% of the data rate of the first frequency discriminator. A corresponding situation applies to the divider setting by means of the third frequency discriminator.

The controller 11 can use the count result to set the frequency divider in the control loop on the basis of a stored table 18.

Other embodiments, including analog embodiments, are also, of course, feasible for the second and third frequency discriminators.

The pull-in range of the oscillator and the setting steps of the frequency divider must be matched to one another. It must always be possible to vary the oscillator frequency sufficiently that the second frequency discriminator FD2 is sufficient for rough frequency control, until the first frequency discriminator FD1 can then carry out the fine frequency adjustment. If the oscillator can be tuned, for example, over one octave, then it is possible to use a frequency divider which can be switched in binary steps. The feasibility to switch off the output signals from the frequency discriminators depends on the embodiment and the dimensioning.

Once the frequency has been set roughly by the frequency control signal RF2, the first frequency discriminator FD1 supplies a control signal RF1 for a further approximation of the frequencies by the data signal and clock signal until the catchment range of the phase discriminator PD is reached. To this end, the first frequency discriminator FD1 compares the reference signal (data signal) and the comparison signal derived from the oscillator, the clock signal TS, and normally emits a frequency control voltage RF1 which is proportional to the frequency difference AB.

One suitable frequency discriminator is known from “A Phase-Locked Loop with Digital Frequency Comparator for Timing Signal Recovery”, National Telecommunication Conf. Rec., paper 14.4, 1979, pages 237-241, J. A. Afonso, A. J. Ouiterio, and D. S. Arantes and is illustrated in FIG. 2 of this reference, containing two input D-multivibrator stages, whose data inputs are respectively supplied with a clock signal and a clock signal shifted through 90°. The clock signals subdivide one period of the clock signal into four time intervals. The clock inputs of the two input D multivibrator stages are supplied with the data signal (or with clock pulses DSI derived from this signal). The input D multivibrator stages are each followed by further multivibrator stages, which are triggered by the data signal, in order to allow comparison with the previous sample values and to assess this comparison in an evaluation logic device. The clock signals define time intervals. If the data flanks pass through different time intervals, then there is a frequency difference between the clock signal and the data signal. The time intervals may, of course, also be defined by a frequency divider.

One suitable circuit arrangement for the first frequency discriminator FD1, which supplies output pulses synchronized to the clock signal, is illustrated in FIG. 5 and is described in the following text. This likewise uses two input multivibrator stages 21 and 22, whose data inputs are likewise supplied with clock signals TS and TS1 shifted through 90° with respect to one another, and which are likewise triggered by the flanks DSI of a data signal DS. The first input multivibrator stage 21 is followed by further multivibrator stages 23 and 25, and the second input multivibrator stage 22 is followed by multivibrator stages 24 and 26, which are clocked by the clock signal TS (in principle, the delayed clock signal can also be used for clocking).

The upper part of the timing diagram in FIG. 6 shows the profile of the clock signals TS and TS1 and of the output voltages from the input multivibrator stages 21 and 22 in the situation where the frequency of the clock signal is lower than the frequency of the data signal (f_{TS}<f_{DS}); the central part shows the situation where the frequency of the clock signal is higher than the frequency of the data signal (f_{TS}>f_{DS}), and the lower part shows the situation where the frequencies match, and the phase locked loop is locked in (the flanks of the data signal coincide with those of the clock signal TS, so that these sample values are uncertain and should not be evaluated). The sample values of the clock signals which each indicate the time interval in which a flank of the data signal occurs are transferred synchronously to those of the multivibrator stages 23, 25 and 24, 26, whose output signals at Q3-Q6 are then evaluated in the evaluation logic device.

It should also be mentioned that delay elements T1 and T2 may be provided in a manner known per se in the circuit arrangement, to increase the cut-off frequency of the circuit. The evaluation circuit must then be adapted appropriately. The detectable frequency range can be extended by lengthening the shift registers 211, 23, 25 and 22, 24, 26.

Up pulses Pu are emitted when the clock frequency f_{TS} is less than the data rate and should thus be increased (u—up), and the down pulses Pd (d—down) are emitted when the clock frequency is higher than the data rate and should be reduced.

The function of the circuit can thus be explained in simplified form: if the clock signal TS and the data signal DS are synchronized, the sampled logic states of the clock signals do not change. If the frequency of the clock signal is too low in comparison with the data rate, then, for example if the already sampled logic states of the clock signals TS and TS1 were 1 and 0, that is to say the data flank in the time interval marked in this way was missing, the output signals at Q5 and Q6 will likewise be 1 and 0 after two pulses of the clock signal TS. If there is a correspondingly major phase error φ=Δf t between the clock signal and the data signal, the flank of the data signal will fall in another time interval, and the next changed logic states, and hence the logic output signals at Q3 and Q4, will be 0 and 0, etc. Expressed in other words, the flank of the data signal falls in the adjacent time interval, which is defined by the clock signals. If, on the other hand, the frequency of the clock signal is higher than that of the data rate then—if the already sampled states of the two clock signals were 1 and 0, the next sampled, changed logic states will be 0 and 0. The greater the frequency errors, the more frequently the correction pulses occur, which are used as a control criterion, as digital or analog signals.

In principle, it is possible to evaluate the transitions between all adjacent logic states of the sample signals which correspond to adjacent time intervals. However, it is also possible to restrict this to the transition between two time intervals or sample values, in this case 0, 0 and 1, 0 (printed in bold text in the decision table), which are particularly noncritical when the control loop is locked in. According to the decision table 1, only the particularly critical transitions are not evaluated.

Decision Table 1:

| | | | | Pulses to |
|---|---|---|---|---|
| Q3 | Q5 | Q4 | Q6 | VCO |
| 0 | 0 | 0 | 0 | — |
| 0 | 0 | 0 | 1 | down |
| 0 | 0 | 1 | 0 | up |
| 0 | 0 | 1 | 1 | — |
| 0 | 1 | 0 | 0 | up |
| 0 | 1 | 0 | 1 | — |
| 0 | 1 | 1 | 0 | — |
| 0 | 1 | 1 | 1 | — |
| 1 | 0 | 0 | 0 | down |
| 1 | 0 | 0 | 1 | — |
| 1 | 0 | 1 | 0 | — |
| 1 | 0 | 1 | 1 | — |
| 1 | 1 | 0 | 0 | — |
| 1 | 1 | 0 | 1 | up |
| 1 | 1 | 1 | 0 | down |
| 1 | 1 | 1 | 1 | — |

Another expedient evaluation is shown in a second decision table, which takes account of problems associated with the transfer of the sampled clock signal states by means of the sample signal.

2^{nd} Decision Table:

| | | | | Pulses to |
|---|---|---|---|---|
| Q3 | Q5 | Q4 | Q6 | VCO |
| 0 | 0 | X | X | — |
| 0 | 1 | 0 | 0 | up |
| 0 | 1 | 0 | 1 | up |
| 0 | 1 | 1 | 0 | up |
| 0 | 1 | 1 | 1 | — |
| 1 | 0 | 0 | 0 | down |
| 1 | 0 | 0 | 1 | down |
| 1 | 0 | 1 | 0 | down |
| 1 | 0 | 1 | 1 | — |
| 1 | 1 | X | X | — |

The associated evaluation logic is illustrated in FIG. 7.

The evaluation logic can also be simplified by dispencing with the multivibrator stages 24 and 26, although shortened output pulses may occur in this case.

2^{nd} Exemplary Embodiment:

| | | | Pulses to |
|---|---|---|---|
| Q3 | Q5 | Q2 | VCO |
| 0 | 0 | X | — |
| 0 | 1 | 0 | up |
| 0 | 1 | 1 | — |
| 1 | 0 | 0 | down |
| 1 | 0 | 1 | — |
| 1 | 1 | X | — |

One period duration can, of course, also be subdivided, for example, into six or more time intervals although this requires more than two parallel processing paths and correspondingly increased complexity for evaluation.

If the loop is locked in with locked phase angles, then it is expedient to switch off the frequency discriminators (via a switching device 12 in FIGS. 1 and 2) since, otherwise, the phase jitter, which can likewise be perceived as a frequency change, via the loop filter would result in additional control signals being supplied to the oscillator. Instead of switching off the control signals, a suitable design of the frequency discriminators can also be used to ensure the same effect.

In order to achieve an optimum control response for the design of the PLL, it is expedient for the loop filter to have a proportional path P for the phase discriminator and at least one integral path I for the frequency discriminators, whose output signals are combined by an adder 17. In order to satisfy the stability conditions required for data transmission, the filter parameters can be switched as a function of the data rate.

The controller 11 can be equipped with a memory M1, M2, which keeps the setting of the PLL constant if the data signal fails, so that resynchronization takes place very quickly.

The method of operation of the control process will be explained once again with reference to the control signals and using FIG. 4. If the bit rate errors are large, the frequency control signal RF2=Z_{D}−Z_{TS} of the second frequency discriminator FD2 first of all readjusts the frequency of the oscillator—as a function of the difference ΔB in the bit rates between the data signal and the clock signal—until the catchment range of the first frequency discriminator FD1 is reached. The amplitude becomes zero here, and the frequency control signal RF2 is switched off. The frequency control signal RF1 of the first frequency discriminator FD1 then ensures accurate matching of the frequencies, until the phase control is carried out by the phase control signal RP of the phase discriminator PD.

The analyses above have been based on an objective measurement of the bit rate by means of a constant reference signal. However, this is not essential. In fact, in accordance with FIG. 1, it is also possible to use the one output clock of the frequency divider 6, in this case the clock signal, TS, as a reference signal. The second frequency discriminator FD2 then compares the clock signal with the digital signal DSF, and once again passes on the control signal to the controller 11. This knows the current divider setting and that which allows operation of the control loop at the bit rate of the applied data signal. It can thus likewise set the frequency divider directly.

The frequency divider setting can also be carried out successively. This is done by checking the control signal determined by the second frequency discriminator. The setting of the frequency divider 6 is varied in steps as a function of a positive or negative result going beyond a threshold value. The control signal of the oscillator 5 can, of course, also be used as an equivalent measurement variable. This can also be used in the embodiments described initially, in order to adjust the frequency divider 6 in the control cut-off region such that the operating frequency of the oscillator is well away from the limit, for example such that it is moved approximately to the center of the pull-in range. Such a limit situation can occur if the division ratio of the frequency divider has been set to a poor value owing to the systematic error.

1. A clock and data regenerator for different data rates having a phase discriminator (PD) and a first frequency discriminator (FD1), to which a data signal (DSF) is supplied as a reference signal, having a loop filter (4) via which an oscillator (5) is driven, and having a frequency divider (6) in the feedback path, whose output signal is supplied as a comparison signal (TS) to the phase discriminator (PD) and to the first frequency discriminator (FD1),
characterized
in that at least one second frequency discriminator (FD2) is provided, which compares the bit rate of the data signal (DSF) with the frequency of the clock signal (TS) emitted from the frequency divider (6), and in that the comparison result governs the division ratio of the frequency divider (5) and supplies a control signal (RS2) which, filtered, controls the oscillator (5).

2. The clock and data regenerator as claimed in claim 1,
characterized
in that the division ratio of the frequency divider (6) is reduced or increased as necessary on the basis of the comparison result of the second frequency discriminator (FD2).

3. The clock and data regenerator as claimed in claim 1,
characterized
in that the division ratio of the frequency divider (6) is set on the basis of the comparison result of the second frequency discriminator (FD2).

4. The clock and data regenerator as claimed in one of the preceding claims,
characterized
in that a controller (11) is provided, which converts the comparison result of the second frequency discriminator (FD2) to a control signal (STT) which governs the division ratio of the frequency divider (5), and also converts the comparison result to a second control signal (RF2) which, filtered, controls the oscillator (5).

5. A clock and data regenerator having a phase discriminator (PD) and a first frequency discriminator (FD1) to which a data signal (DS_{F}) is supplied as a reference signal, having a loop filter (4) via which an oscillator (5) is driven, and having a frequency divider (6) in the feedback path, whose output signal is supplied as a comparison signal (TS) to the phase discriminator (PD) and to the first frequency discriminator (FD1),
characterized
in that a second frequency discriminator (FD2) is provided, which compares the bit rate of the data signal (DS_{F}) with that of the output signal (TS) from the frequency divider (6),
with the comparison result being converted to a second control signal (RF2) which, filtered, controls the oscillator (5), and
in that a third frequency discriminator (FD3) is provided, to which a constant reference signal (KF) is supplied in order to determine the bit rate of the data signal (DS_{F}), and whose output signal is converted to a control signal (STT), which governs the division ratio of the frequency divider (5).

6. The clock and data regenerator as claimed in claim 5,
characterized
in that a controller (11) is provided, which converts the comparison result of the third frequency discriminator (FD3) to a control signal (STT) which governs the division ratio of the frequency divider (5),
and, furthermore, converts the comparison result of the second frequency discriminator (FD2) to a second control signal (RF2) which, filtered, controls the oscillator (5).

7. The clock and data regenerator as claimed in one of claims 1 to 3,
characterized
in that, in order to determine the values for setting the frequency divider (6), the reference signal (KF) is supplied to the second frequency discriminator (FD2) at times.

8. The clock and data regenerator as claimed in one of the preceding claims,
characterized
in that the second frequency discriminator (FD2) and the third frequency discriminator (FD3) assess the step changeovers of the data signal (DS_{F}) in comparison to the step changeovers of the clock signal (TS), of the reference signal (KF) or of the time, in order to use this to determine the control signal (RF2) or the setting signal (STT).

9. The clock and data regenerator as claimed in one of the preceding claims,
characterized
in that the frequency discriminator (FD2, FD3) has a correction element (15), which is used to correct the measured data rate of the data signal (DS).

10. The clock and data regenerator as claimed in one of the preceding claims,
characterized
in that the frequency discriminators (FD1, FD2) do not emit any control signal (RF2, RF3) in the region of the nominal position, or in that their control signals are switched off.

11. The clock and data regenerator as claimed in one of the preceding claims,
characterized
in that means are provided for setting the oscillator (6) to a mid-frequency within its pull-in range, for resynchronization

12. The clock and data regenerator as claimed in one of the preceding claims,
characterized
in that a loop filter (4) is provided for all the discriminators, and is in the form of an integrator or a filter with an integral component.

13. The clock and data regenerator as claimed in one of the preceding claims,
characterized
in that a binary-adjustable frequency divider is provided, and
in that the first oscillator (5) is provided with a pull-in range of at least one octave.

14. The clock and data regenerator as claimed in one of the preceding claims,
characterized
in that means are provided for storing the setting values of the frequency divider and/or of the oscillators (6), and these setting values are used as start values for resynchronization.

15. The clock and data regenerator as claimed in one of the preceding claims,
characterized
in that the loop filter (5) has a proportionality path (P), to which the control signal (RP) of the phase discriminator (PD) is supplied, and has at least one integral path (I), to which the control signal (RF1, RF2) of one of the frequency discriminators (FD1, FD2) is supplied.

16. The clock and data regenerator as claimed in one of the preceding claims,
characterized
in that the filter parameters for the loop filter (5) are set as a function of the data rate.

17. The clock and data regenerator as claimed in one of the preceding claims,
characterized
in that means are provided for correcting the setting of the frequency divider (6) when the pull-in range of the oscillator reaches a limit value.

18. The clock and data regenerator as claimed in one of the preceding claims,
characterized
in that signal conditioning (9) is provided, which converts the received data signal (DS) to a data signal (DSF) which is derived from it and is of the fundamental frequency of the data rate.

19. The clock and data regenerator as claimed in one of the preceding claims,
characterized
in that the first frequency discriminator (FD1) has two input multivibrator stages (20, 21) which are clocked by the flanks of the data signal (DS) or by pulses (DSI) derived from them, in that the data inputs are supplied with different signals (TS, TS1) at the period of the clock signal (TS) for marking four periodic time intervals, which are at least approximately the same, in that, when a flank occurs, the current time interval is stored, in that at least two further multivibrator stages (23, 25) are connected in series with the first input multivibrator stage (20) and are triggered by the clock signal (TS), and in that an evaluation logic device (AL) is connected to the outputs of the multivibrator stages (22, 23, 24) and emits first pulses (Pu) at an excessively low frequency (f_{TS}) of the clock signal (TS) and second pulses (Pd) at an excessively high frequency of the clock signal.

20. The clock and data regenerator as claimed in claim 19,
characterized
in that the data input (D) of the first input multivibrator stage (21) is supplied with the clock signal (TS) at a 1:1 duty ratio, and the data input (D) of the second input multivibrator stage (22) is supplied with a second clock signal (TS1), which is phase-shifted through 90° with respect to the first clock signal (TS), so that one clock signal period is subdivided into four time intervals which are at least approximately the same.

21. The clock and data regenerator as claimed in claim 19 or 20,
characterized
in that each input multivibrator stage (20, 21) is in each case followed by two further multivibrator stages (23, 25; 24, 26), which are clocked by the clock signal (TS) and whose outputs (Q3-Q6) are connected to the evaluation logic device (AL).

22. The clock and data regenerator as claimed in claim 21,
characterized
in that, in order to produce first pulses (Pu) and second pulses (Pd), only the transitions between two noncritical time intervals are in each case evaluated, which correspond to sample value pairs (Q5=0, QG=0 and Q5=1, Q6=0) and which lie on both sides of the ideal sampling time when the phase control loop is locked in.

23. The clock and data regenerator as claimed in claim 20 or 21 to 21,
characterized
in that three adjacent transitions between the time intervals are in each case evaluated in order to produce first pulses (Pu) and second pulses (Pd).
